(19) United States
(12) Patent Application Publication
(10) Pub. No.: US 2022/0203586 A1
(43) Pub. Date: Jun. 30, 2022

(54) METHOD FOR PRODUCING METAL-PLASTIC COMPOSITE COMPONENT, AND METAL-PLASTIC COMPOSITE COMPONENT

(71) Applicant: SHENZHENSHI YUZHAN PRECISION TECHNOLOGY CO., LTD., Shenzhen (CN)

(72) Inventors: GANG LI, Shenzhen (CN); QI-MI HUANG, Shenzhen (CN); BIN DAI, Shenzhen (CN); HUI WANG, Shenzhen (CN)

(21) Appl. No.: 17/561,812

(22) Filed: Dec. 24, 2021

(30) Foreign Application Priority Data
Dec. 30, 2020 (CN) 202011615026.9

(51) Int. Cl. B29C 45/14

(52) U.S. Cl. CPC B29C 45/14311; B29K 2705/00; B29C 2045/14868

(57) ABSTRACT

A method for producing a metal-plastic composite component comprises: forming a metal substrate with a receiving hole; injecting first plastics into the metal substrate to form a metal-plastic blank, wherein the first plastics are filled in the receiving hole; processing the receiving hole and the first plastics for removing a part of the first plastics by at least one cutter to form a receiving space; and injecting second plastics into the metal-plastic blank to form the metal-plastic composite component, wherein the receiving space is filled with the second plastics. With this method, a combination strength of the metal-plastic composite component is enhanced. A metal-plastic composite component is also provided.

### CROSS-REFERENCE TO RELATED APPLICATIONS

This application claims priority to Chinese patent application No. 202011615026.9, filed on Dec. 30, 2020, which is incorporated herein by reference in its entirety.

### FIELD

The subject matter herein generally relates to metal-plastic composite component manufacture field, specifically relates to a method for producing a metal-plastic composite component and a metal-plastic composite component.

### BACKGROUND

A metal-plastic composite component is widely used in a frame of the electronic device. The method for manufacturing the frame includes disposing several sections of metal components in circular recess of a mold and injecting plastic material into the closed mold to form the frame. The metal components are used for supporting. Signal transmission paths are formed in the plastic material disposed in gaps between two adjacent metal components. The manufacture of the frame is a one-step forming.

The thin frame becomes more popular, and in a process for manufacturing the thin frame, parameters, such as an injecting molding pressure, a plastic injecting flow rate, require a high accuracy. When directly injecting the plastic into the mold, a deviation of the parameter will cause the combination between the metal and the plastic to be instability, or a deformation at ends of the metal being connected with the plastic. Thus, in a case where the metal-plastic composite component is crashed or fallen down, a gap may generate at the combination position, and a quality of the frame is reduced. The deformation being viewed by users will reduce a user feeling.

There is room for improvement in the art.

### BRIEF DESCRIPTION OF THE FIGURES

Implementations of the present disclosure will now be described, by way of example only, with reference to the attached figures.

FIG. 1 is a flowchart illustrating a method for producing a metal-plastic composite component according to the present disclosure.

FIGS. 2A-2E are cross-section diagrams illustrating an embodiment of a metal-plastic composite component in different manufacturing steps according to the present disclosure.

FIG. 3 is a diagram illustrating a first embodiment of a structure contacting first plastics and a second plastic according to the present disclosure.

FIG. 4 is a diagram illustrating a second embodiment of a structure contacting first plastics and a second plastic according to the present disclosure.

FIG. 5 is a diagram illustrating a third embodiment of a structure contacting first plastics and second plastics according to the present disclosure.

FIG. 6 is a detail flowchart illustrating a first embodiment of block S10 in the method of FIG. 1 according to the present disclosure.

FIG. 7 is a detail flowchart illustrating an embodiment of block S20 in the method of FIG. 1 according to the present disclosure.

FIG. 8 is a detail flowchart illustrating an embodiment of block S30 in the method of FIG. 1 according to the present disclosure.

FIG. 9 is a detail flowchart illustrating an embodiment of block S40 in the method of FIG. 1 according to the present disclosure.

FIG. 10 is a detail flowchart illustrating a second embodiment of block S10 in the method of FIG. 1 according to the present disclosure.

FIG. 11 is a diagram illustrating an embodiment of the metal-plastic composite component viewed from a first angle according to the present disclosure.

FIG. 12 is an exploded diagram illustrating an embodiment of the metal-plastic composite component according to the present disclosure.

FIG. 13 is a diagram illustrating an embodiment of the metal-plastic composite component viewed from a second angle according to the present disclosure.

### DETAILED DESCRIPTION

The present disclosure is described with reference to accompanying drawings and the embodiments. It will be understood that the specific embodiments described herein are merely part of all embodiments, not all the embodiments. Based on the embodiments of the present disclosure, it is understandable to a person skilled in the art, any other embodiments obtained by persons skilled in the art without creative effort shall all fall into the scope of the present disclosure.

The relationships of orientations or positions denoted by the terms of terms “center”, “longitudinal”, “lateral”, “length”, “width”, “thickness”, “up”, “down”, “left”, “right”, “horizontal”, “left”, “top”, “bottom”, “inside”, “outside”, “clockwise”, “anticlockwise” used herein refer to those illustrated in the accompany drawings, which are only for conveniently describing the invention and simplifying the description, rather than indicate or imply that a device or member has to be in a specific orientation or configured or operated in a specific orientation. In addition, the terms of “first” and “second” are for the purpose of describing only and should not be constructed to indicate or imply the relative importance. In the present disclosure, the term of “some” means two or more than two, unless otherwise expressly stated.

In the present disclosure, unless otherwise expressly stated, the terms “mounted”, “link”, and “connect” should be understood broadly, unless otherwise specified and defined, for example, they may be a fixed connection or a removable connection, they may be mechanical connection or electrical connection, and also inner communication between two members, they may direct connection, and also indirect connection via a medium, the skilled persons in the art may understand the meanings of above terms according to specific situations.

In the present disclosure, unless otherwise expressly stated, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

The following contents in the present disclosure provide different examples for the implementation of the different structures in this application. To simplify the application, the content below describes the components and settings for a specific example. Nevertheless, the components and settings are only for demonstration purpose, not to be considered as restrictions to this application. Furthermore, the reference number and/or letter in this application can be repetitively used in different examples. It aims to simplify and clarify the application, with no intention on indicating the relationship between different examples and/or settings. In addition, this application provides examples of several different specific technology and material, which can be extended to implementations on other technology and/or material by the technical staff within the same field.

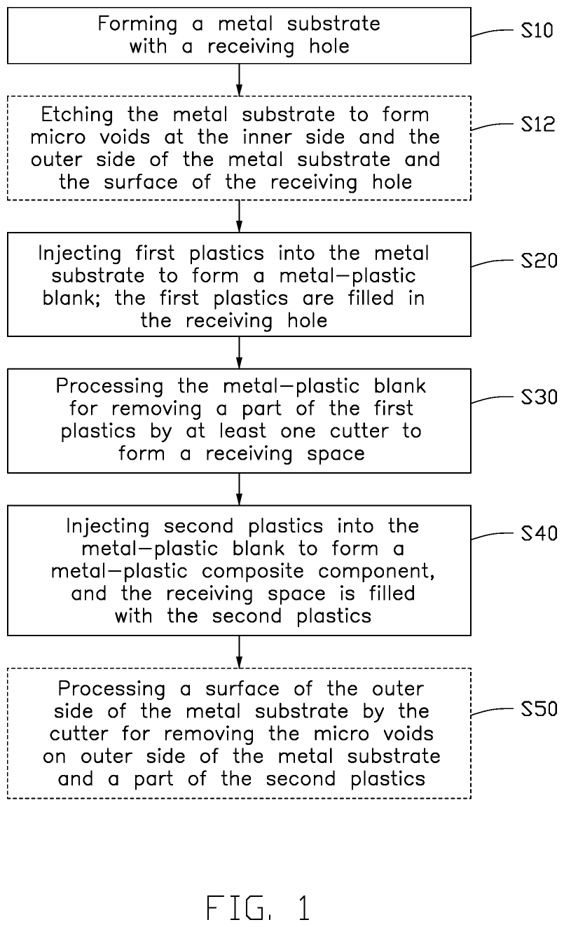

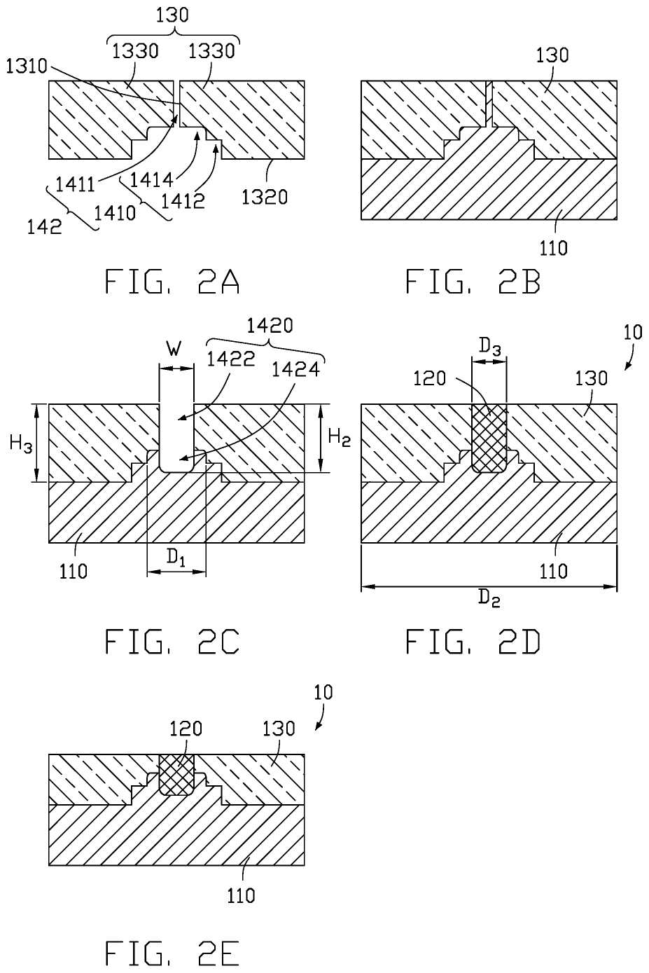

FIGS. 1 and 2 illustrate a first embodiment of a method for producing a metal-plastic composite component, and the metal-plastic composite component in different manufacturing steps. The method may comprise at least the following steps, which also may be re-ordered:

In block S10, a metal substrate 130 with a receiving hole 142 is formed.

In detail, as shown in FIG. 2A, a metal blank is provided, and the receiving hole 142 is formed at the metal blank by drilling or other manner. The metal blank is made in a mechanical work manner or in a molding casting manner. The metal blank can be made of stainless steel, aluminum, aluminum alloy, or titanium alloy.

In block S20, first plastics 110 are injected into the metal substrate 130 to form a metal-plastic blank, and the first plastics 110 are filled in the receiving hole 142.

In detail, as shown in FIG. 2B, the metal substrate 130 is injected by an injecting molding machine for filling the first plastics 110 in the receiving hole 142. The metal-plastic blank is formed by combining the metal substrate 130 and the first plastics 110. Preferably, the first plastics 110 are fully filled in the receiving hole 142.

In block S30, the metal-plastic blank is processed for removing a part of the first plastics 110 by at least one cutter, and a receiving space 1420 is formed.

In detail, as shown in FIG. 2C, the cutter can be a CNC milling cutter. A depth H₃ of the receiving hole 142 is larger than a depth H₂ of the receiving space 1420. The depth H₃ is larger than 0.9 millimeter (mm). A width D₁ of the receiving hole 142 is larger than a width W of the receiving space 1420.

Preferably, the width D1 of the receiving hole 142 can be less or equal to the width W of the receiving space 1420. Preferably, a length of the receiving hole 142 is equal to a length of the receiving space 1420. A cross-sectional area of the receiving hole 142 is larger than a cross-sectional area of the receiving space 1420. Preferably, the cross-sectional area of the receiving hole 142 can be less than or equal to the cross-sectional area of the receiving space 1420.

Preferably, the CNC uses the receiving hole 142 as a manufacturing reference point and digs the first plastics 110 in the metal-plastic blank to remove a part of the first plastics 110, and the receiving space 1420 is formed.

Preferably, after the part of the first plastics 110 is removed by the CNC, an upper surface of the first plastics 110 can be a flat surface, a concave surface, or a convex surface.

In block S40, second plastics 120 are injected into the metal-plastic blank to form a metal-plastic composite component 10, and the receiving space 1420 is filled with the second plastics 120.

In detail, as shown in FIG. 2D, the first plastics 110 and the second plastics 120 are made of a same material, or different materials, such as PE, PP, PVC, ABS, and so on. A height of the first plastics 110 in the metal-plastic composite component 10 can be larger than, equal to, or less than a height of the second plastics 120. A width D₂ of the first plastics 110 is larger than a width D₃ of the second plastics 120. Preferably, the width D₂ of the first plastics 110 also can be less than or equal to the width of the second plastics 120. Preferably, the length of the first plastics 110 is equal to a length of the second plastics 120. Preferably, the cross-sectional area of the first plastics 110 is larger than a cross sectional area of the second plastics 120. Preferably, the cross-sectional area of the first plastics 110 also can be less than or equal to the cross-sectional area of the second plastics 120.

Preferably, the upper surface of the first plastics 110 is smoothly contacted with a bottom surface of the second plastics 120. Otherwise, the first plastics 110 can embed with the second plastics 120.

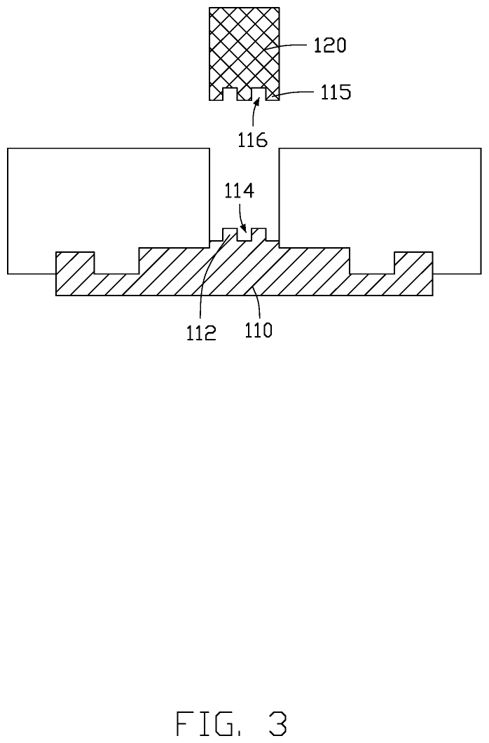

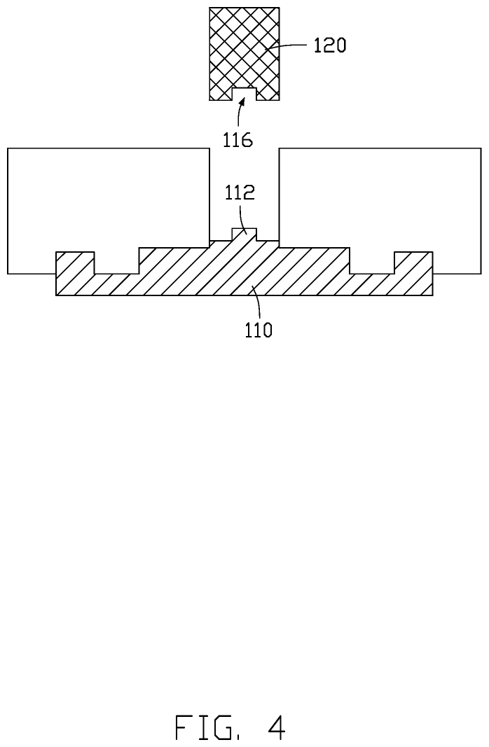

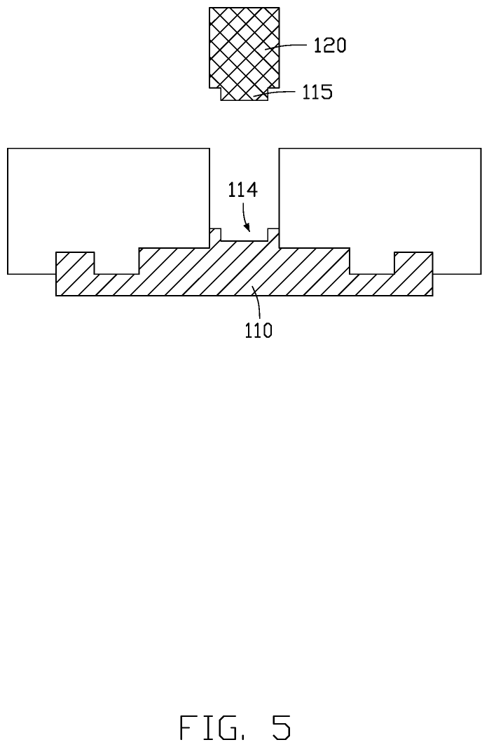

In detail, as shown in FIG. 3, in a first embodiment, at least two first projections 112, at least two first indentations 114 are formed at the upper surface of the first plastics 110 by the cutter, and thus, when injecting the second plastics 120, the second plastics 120 can also be formed with at least two second projections 115 and at least two second indentations 116. The second projections 115 and the second indentations 116 of the second plastics 120 are respectively embedded with the first projections 112 and the first indentations 114. As shown in FIG. 4, in a second embodiment, one first projection 112 is formed at the upper surface of the first plastics 110 by the cutter, and thus, when injecting the second plastics 120, the second plastics 120 coat the first projection 112. As shown in FIG. 5, in a third embodiment, the second plastics 120 can be embedded into the first plastics 110. In detail, a first indentation 114 is formed at the upper surface of the first plastics 110 by the cutter, and thus, when injecting the second plastics 120, a part of the second plastics 120 is embedded into the first indentation 114.

In another embodiment, as shown in FIGS. 1 and 2, the method further includes:

In block S12, the metal substrate 130 is etched to form micro voids on an inner side 1310 and an outer side 1320 of the metal substrate 130, and an inter surface of the receiving hole 142.

In detail, the micro voids fill with plastic and can improve a combination strength between the metal substrate 130 and the plastic while injecting the plastic. A diameter of each micro void is in a range from 30 μm to 80 μm, and a depth of each micro void is in a range from 30 μm to 80 μm.

The etching process can be a laser etching process, a laser carving process, or a chemical etching process. In other embodiments, other etching processes can be also used for forming the micro voids on the inner side 1310 and the outer side 1320 of the metal substrate 130, and the inter surface of the receiving hole 142.

In another embodiment, as shown in FIGS. 1 and 2, the method further includes:

In block S50, a surface process is executed by the cutter for removing the micro voids on the outer side 1320 of the metal substrate 130 and a part of the second plastics 120.

In detail, as shown in FIG. 2E, the cutter can be a copy cutter. The surface process can be a milling process for removing the micro voids on the outer side of the metal substrate 130, surfaces of the metal substate 130 and the plastic are smooth for improving an appearance quality, and an experience feeling of user is improved.

Preferably, a surface roughness of the outer side of the metal substrate 130 and the second plastics 120 is less than Ra0.8. Preferably, when milling the outer side of the metal-plastic composite component 10, edges of the outer side of the metal-plastic composite component 10 are chamfered in a circular shaped.

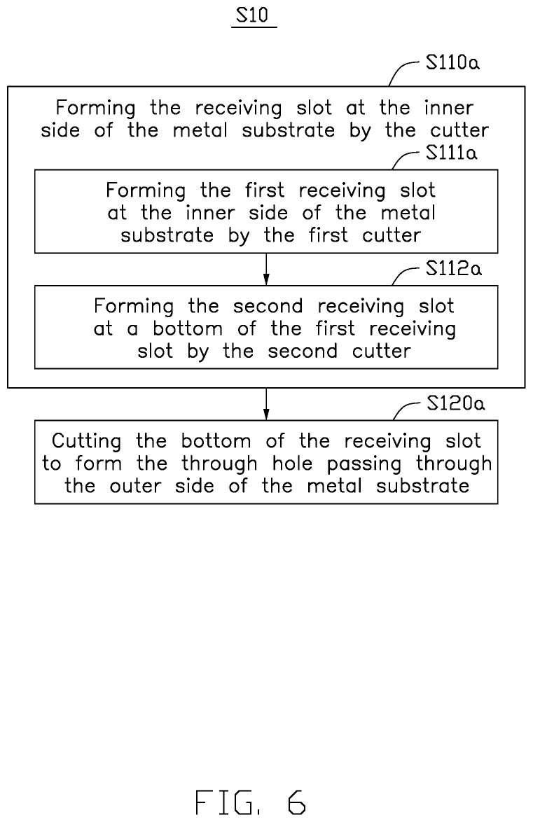

Referring to FIGS. 6 and 2A, in the first embodiment, the receiving hole 142 includes a receiving slot 1410 and a through hole 1411. The step where a metal substrate 130 with a receiving hole 142 is formed includes:

In block S110a, the receiving slot 1410 is formed at an inner side 1310 of the metal substrate 130 by the cutter.

In detail, a depth of the receiving slot 1410 is in a range from 0.3 mm to 1 mm. Preferably, the depth of the receiving slot 1410 is 0.8 mm. A width of the receiving slot 1410 is larger than or equal to 1.5 mm. Preferably, the width of the receiving slot 1410 is 1.5 mm.

In block S120a, the cutter cuts at a bottom of the receiving slot 1410 and passes through the outer side 1320 of the metal substrate 130 to form the through hole 1411.

In detail, a depth of the through hole 1411 is in a range from 0.3 mm to 0.5 mm. Preferably, the depth of the through hole 1411 is 0.4 mm. A width of the through hole 1411 is in a range from 0.6 mm to 1.5 mm. Preferably, the depth of the through hole 1411 is 0.6 mm. The through hole 1411 communicates with the receiving slot 1410 to form two metal portions 1330 spaced from each other. The through hole 1411 and the receiving slot 1410 are disposed between the two metal portions 1330. A roughness of one of the inner side of the metal substrate 130 and the surface of the receiving slot 1410 is in a range from Ra10 to Ra30; a roughness of one of the outer side of the metal substrate 130 and the surface of the receiving slot 1410 is in a range from Ra 0.5 to Ra1.6.

In one embodiment, the receiving slot 1410 includes a first receiving slot 1412 and a second receiving slot 1414. The at least one cutter includes a first cutter and a second cutter. The step where the receiving slot 1410 is formed at an inner side 1310 of the metal substrate 130 by the cutter includes:

In block S111a, the first receiving slot 1412 is formed at the inner side 1310 of the metal substrate 130 by the first cutter.

In detail, a width of the first receiving slot 1412 is larger than or equal to 1.5 mm. Preferably, the width of the first receiving slot 1412 is 1.5 mm. A depth of the first receiving slot 1412 is in a range from 0.3 mm and 0.8 mm. Preferably, the first receiving slot 1412 is 0.5 mm. The first cutter is an end mill.

In block S112a, the second receiving slot 1414 is formed at a bottom of the first receiving slot 1412 by the second cutter, and a cross-sectional area of the first receiving slot 1412 is larger than a cross-sectional area of the second receiving slot 1414.

In detail, a width of the second receiving slot 1414 is in a range from 0.5 mm to 1.5 mm. Preferably, the width of the second receiving slot 1414 is 0.8 mm. A depth of the second receiving slot 1414 is less than 0.8 mm. Preferably, the depth of the second receiving slot 1414 is 0.3 mm.

Cross-sectional areas of the first receiving slot 1412 and the second receiving slot 1414 are cut along a direction perpendicular to an open direction. The cross-sectional area of the first receiving slot 1412 is larger than the cross-sectional area of the second receiving slot 1414, and thus, a tapped slot structure of the receiving slot 1410 is formed for enhancing a combination strength between the receiving slot 1410 and the plastic.

An inner angle of the second receiving slot 1414 is a circular chamfer R, a stress concentration of the metal-plastic composite component 10, which causes the metal substrate 130 to be separated from the plastic, is avoided if the metal-plastic composite component is crashed or fallen down. In detail, the circular chamfer R is 0.2 mm.

Preferably, the second cutter is a bull mill.

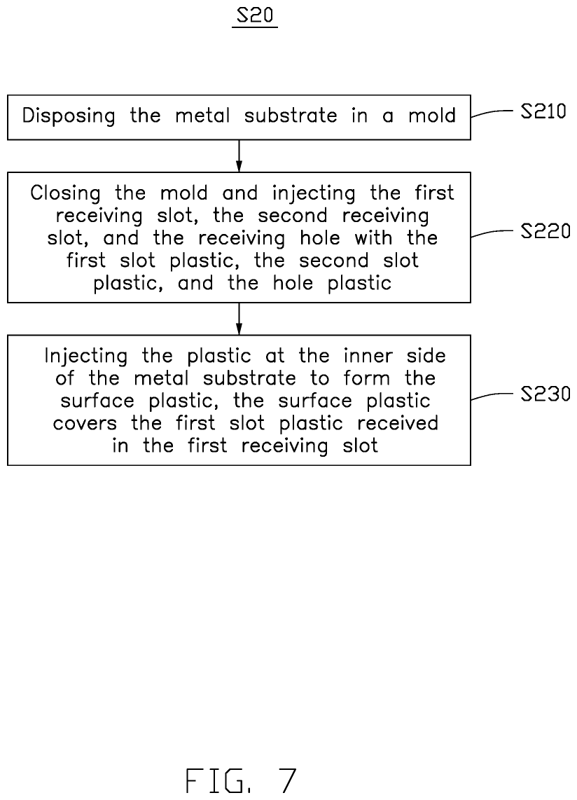

Referring to FIGS. 7 and 2 B, in one embodiment, the first plastics 110 include a first slot plastic, a second slot plastic, and a hole plastic. The step where first plastics 110 are injected into the metal substrate 130 to form a metal-plastic blank includes:

In block S210, the metal substrate 130 is disposed in a mold.

In block S220, the mold is closed, and the first receiving slot 1412, the second receiving slot 1414, and the through hole 1411 are injected with the first slot plastic, the second slot plastic, and the hole plastic.

In detail, the first slot plastic, the second slot plastic, and the hole plastic can be separately injected, or also can be injected together. An injection manner is selected based on the mold.

The materials of the first slot plastic, the second plastics, and the hole plastic can be same, and also can be different from each other.

In one embodiment, the first plastics 110 can include a surface plastic. The step where first plastics 110 are injected into the metal substrate 130 to form a metal-plastic blank further includes:

In block S230, the inner side of the metal substrate 130 is injected to form the surface plastic, the surface plastic covers the first slot plastic received in the first receiving slot 1412.

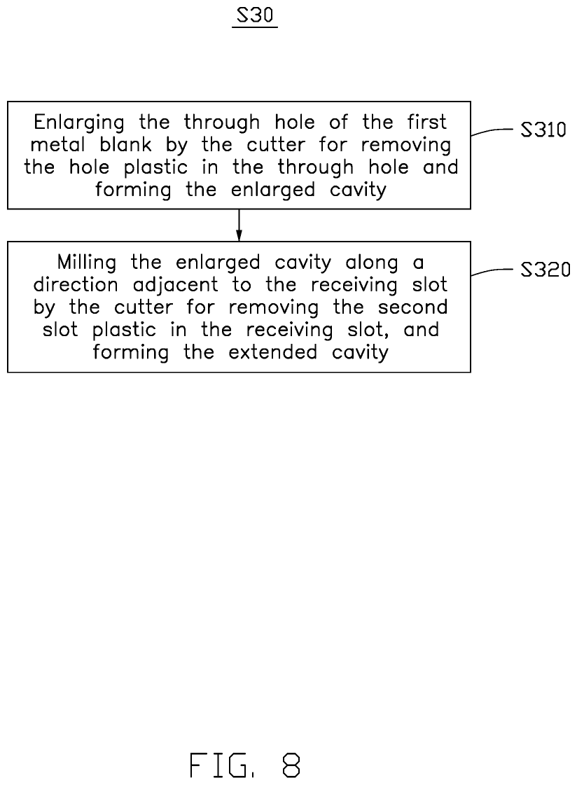

Referring to FIGS. 8 and 2C, in one embodiment, the receiving space 1420 includes an enlarged cavity 1422 and an extended cavity 1424. The step where the metal-plastic blank is processed for removing a part of the first plastics 110 by a cutter, and a receiving space 1420 is formed includes:

In block S310, the through hole 1411 of the first metal blank is enlarged by the cutter for removing the hole plastic in the through hole 1411 and the enlarged cavity 1422 is formed.

In detail, the cutter is a T-cutter in a sharp corner. A width of the enlarged cavity 1422 is in a range from 0.6 to 1.5 mm. Preferably, the width of the enlarged cavity 1422 is 1.5 mm. A depth of the enlarged cavity 1422 is in a range from 0.3 mm to 0.5 mm. Preferably, the depth of the enlarged cavity 1422 is 0.4 mm. A cross-sectional area of the enlarged cavity 1422 is larger than the cross-sectional area of the through hole 1411.

In detail, the cross-sectional area of each of the enlarged cavity 1422 and the through hole 1411 is the cross-sectional area taken along a direction perpendicular to the opening direction.

In block S320, the cutter mills the enlarged cavity 1422 along a direction adjacent to the receiving slot 1410 for removing the second slot plastic in the receiving slot 1410, and the extended cavity 1424 is formed.

In detail, the cutter is a T-cutter in a rounded corner, an inner angle of the extended cavity 1424 is a circular chamfer, a width of the extended cavity 1424 is in a range from 0.5 mm to 1.5 mm. Preferably, the width of the extended cavity 1424 is 1.5 mm. A depth of the extended cavity 1424 is in a range from 0.2 mm to 0.4 mm. Preferably, the depth of the extended cavity 1424 is 0.3 mm. A distance between a bottom surface of the extended cavity 1424 and a bottom surface of the second receiving slot 1414 is larger than the depth of the second receiving slot 1414, and thus, the extended plastic (described in detail later) is passed through the second slot plastic and is embedded into the first slot plastic for enhancing a combination stability between the extended plastic and the first plastics 110.

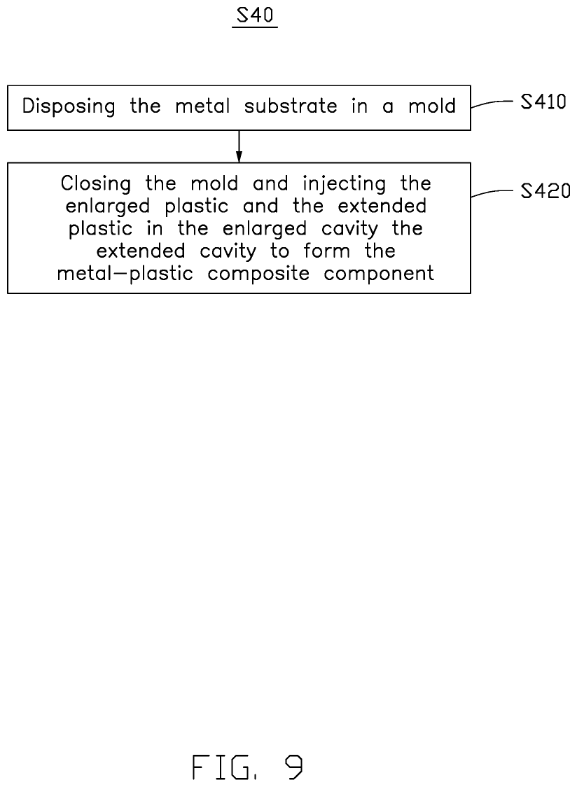

Referring to FIGS. 9 and 2D, in one embodiment, the second plastics 120 include an enlarged plastic and the extended plastic. The step where the second plastics 120 are injected into the metal-plastic blank to form a metal-plastic composite component 10 includes:

In block S410, the metal blank is disposed in a mold.

In block S420, the mold closed, and the enlarged cavity 1422, the extended cavity 1424 are respectively injected with the enlarged plastic and the extended plastic to form the metal-plastic composite component 10.

In detail, the inner angle of the extended cavity 1424 is a circular chamfer r. A stress concentration of the metal-plastic composite component 10, which causes the metal substrate 130 to be separated from the plastic, is avoided if the metal-plastic composite component is crashed or fallen down. In detail, the circular chamfer r is 0.2 mm.

Based on the method for producing the metal-plastic composite component 10, the metal substrate 130 is formed with two injecting operations while forming the metal-plastic composite component 10. A first injecting operation forms the first plastics 110 on the metal substrate 130 for enhancing a strength of the metal substrate 130 and preventing the metal substrate 130 from being deformed due to a pressure of a second injecting operation. The metal substrate 130 is counterbored for removing a deformed portion, and then the second injecting operation is executed for forming the second plastics 120 on the metal substrate 130. The strength of the combination between the metal and the plastic is enhanced. A total quality of the metal-plastic composite component 10 is improved, a probability of viewing a deformed metal substrate 130 from appearance is reduced. A user feeling of the metal-plastic composite component 10 is improved. Besides, the method is simple and in a strong operability, thus it is easy for a scale production and the efficiency of processing the metal-plastic composite component 10 is improved.

In one embodiment, the first slot plastic 1110, the second slot plastic 1120, the surface plastic 1130, the enlarged plastic, and the extended plastic can be made of a same material, or also can be made of different materials. The materials can be PE, PP, PVC, ABS, or the like.

The metal-plastic composite component 10 is used in an electronic device. Signals of the electronic device is transmitted from the first slot plastic 1110, the second slot plastic 1120, the surface plastic 1130, the enlarged plastic, and the extended plastic. It needs to be understood that, while cutting to form the receiving space 1420, metal debris are formed. The metal debris are easily remained at a bottom of the extended cavity 1424 without entirely cleaning off. The bottom surface of the extended cavity 1424 is spaced apart from the bottom surface of the second receiving slot 1414 in a specified distance in the present disclosure, thus a distraction, which is caused by the metal debris being connected to the metal substrate 130, is avoided while transmitting of the signals in the electronic device.

In a second embodiment, the method for producing the metal-plastic composite component 10 is similar to the first embodiment. The difference is the block S10. The metal substrate 130 in the first embodiment can be made of metal material in a complete mold. The metal substrate 130 in the present embodiment is made of two pieces of materials. The block S10 in the present embodiment will described as below.

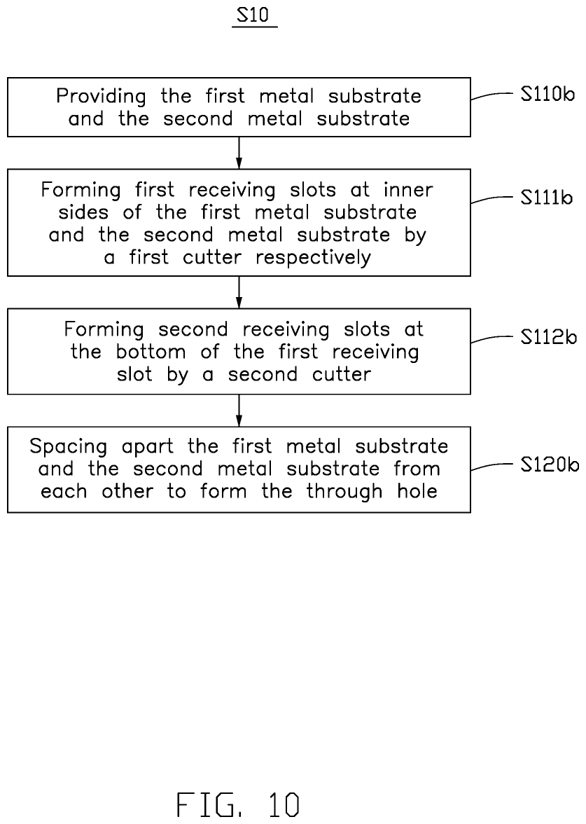

Referring to FIGS. 10 and 2A, in one embodiment, the receiving hole 142 includes a receiving slot 1410 and a through hole 1411. The metal substrate 130 includes a first metal substrate and a second metal substrate. The step where a metal substrate 130 with a receiving hole 142 is formed includes:

In block S110b, the first metal substrate and the second metal substrate are provided.

In detail, the first metal substrate and the second metal substrate can be made in a machine processing manner or a casting molding manner.

In block S111bb, first receiving slots 1412 are formed at inner sides of the first metal substrate and the second metal substrate by a first cutter respectively.

In detail, a width of the first receiving slot 1412 is equal to or larger than 1.5 mm. Preferably, the width of the first receiving slot 1412 is 1.5 mm. A depth of the first receiving slot 1412 is in a range from 0.3 mm to 0.8 mm. Preferably, the depth of the first receiving slot 1412 is 0.5 mm. Preferably, the first cutter is an end mill.

In block S112b, second receiving slots 1414 are formed at the bottom of the first receiving slot 1412 by a second cutter, and a cross-sectional area of the first receiving slot 1412 is larger than a cross-sectional area of the second receiving slot 1414. The circular chamfer R of the second receiving slot 1414 is 0.2 mm. The second cutter is a bull mill.

In block S120b, the first metal substrate and the second metal substrate are spaced apart from each other to form the through hole 1411.

In detail, a depth of the through hole 1411 is in a range from 0.3 mm to 0.5 mm. Preferably, the depth of the through hole 1411 is 0.4 mm. A width of the through hole 1411 is in a range from 0.6 mm to 1.5 mm. Preferably, the width of the through hole 1411 is 0.6 mm.

By comparing with the first embodiment, the first metal substrate and the second metal substrate are spaced apart from each other to form the through hole 1411, thus the step of S120a in the first embodiment can be omitted. Meantime, in the first embodiment, the processing of the receiving slot 1410 is unable to directly view by the user for determining a performance of the receiving slot 1410. In the second embodiment, the first receiving slot 1412 and the second receiving slot 1414 milling by the cutter can be directly viewed by the user, and the processing efficiency of the receiving slot 1410 is improved.

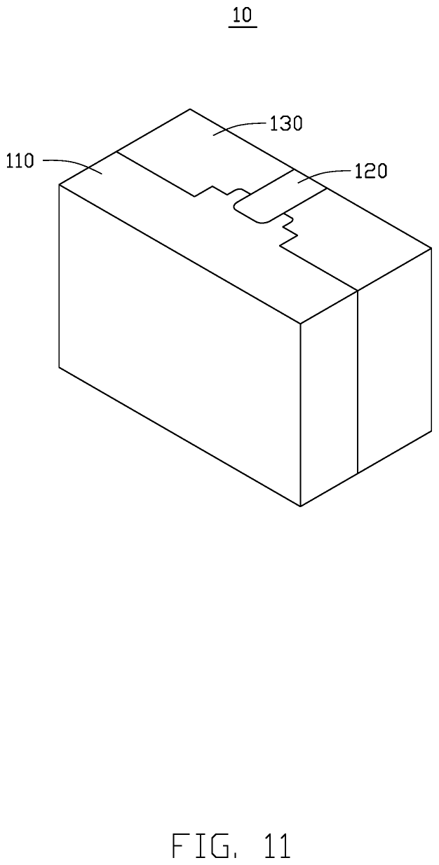

FIG. 11 illustrates a metal-plastic composite component 10 viewed from a first angle. The metal-plastic composite component 10 is made by the above method. The metal-plastic composite component 10 includes first plastics 110, second plastics 120, and a metal substrate 130. The first plastics 110 are connected with the second plastics 120.

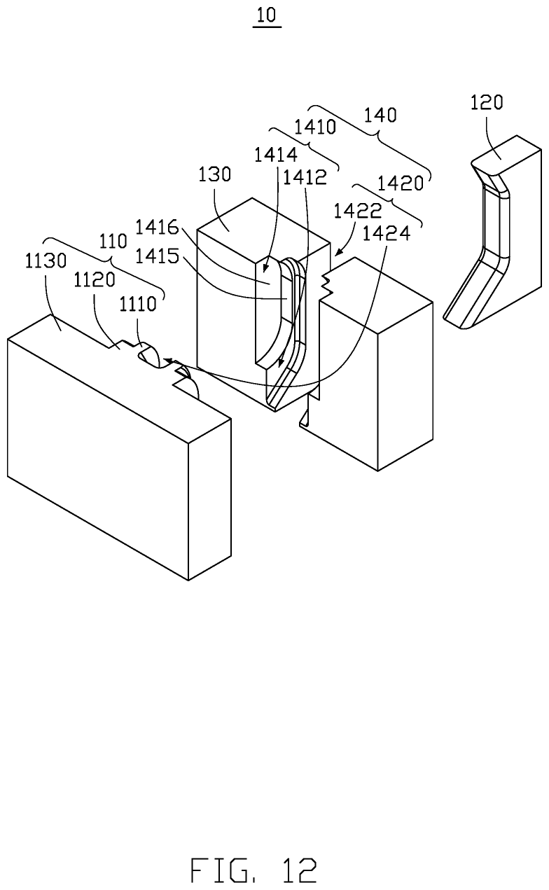

Referring to FIG. 12, the metal substrate 130 defines a hole 140. The first plastics 110 and the second plastics 120 are injected and filled in the hole 140.

In one embodiment, the hole 140 includes a receiving slot 1410 and a receiving space 1420. The receiving slot 1410 is disposed at inner side of the metal substrate 130 for receiving the first plastics 110. The receiving space 1420 is communicated with the receiving slot 1410 and is disposed at an outer side of the metal substrate 130 for receiving the second plastics 120.

A cross-sectional area of the receiving slot 1410 along a direction perpendicular to an opening direction of the receiving slot 1410 is larger than a cross-sectional area of the receiving space 1420. The receiving slot 1410 receives the first plastics 110 and a part of the second plastics 120.

In one embodiment, the receiving slot 1410 includes a first receiving slot 1412 and a second receiving slot 1414. The first receiving slot 1412 is formed at the inner side of the metal substrate 130. The second receiving slot 1414 is formed at a bottom of the first receiving slot 1412 and communicates with the receiving space 1420. A cross-sectional area of the first receiving slot 1412 is larger than a cross-sectional area of the second receiving slot 1414. A roughness of one of the inner side of the metal substrate 130 and the surface of the receiving slot 1410 is in a range from Ra10 to Ra30; a roughness of one of the outer side of the metal substrate 130 and the surface of the receiving slot 1410 is in a range from Ra 0.5 to Ra1.6.

The cross-sectional areas of the first receiving slot 1412 and the second receiving slot 1414 are taken along a direction perpendicular to an opening direction of the hole 140. The inner side and the outer side of the metal substrate 130 are opposite sides.

In one embodiment, the second receiving slot 1414 includes a sidewall 1415 and a bottom wall 1416. The sidewall 1415 communicates with the first receiving slot 1412.

A joint between the bottom wall 1416 and the sidewall 1415 forms a circular chamfer R for avoiding a stress concentration at a joint of the metal substrate 130 and the first plastics 110, and thus, a separation of the metal substrate 130 and the first plastics 110 in the metal-plastic composite component 10 is avoided if the metal-plastic composite component is crashed or fallen down. A combination strength of the first plastics 110 and the metal substrate 130 is improved. Preferably, the circular chamfer R is 0.2 mm.

In one embodiment, the receiving space 1420 includes an enlarged cavity 1422 and an extended cavity 1424. The enlarged cavity 1422 is defined at the outer side of the metal substrate 130. The extended cavity 1424 communicates with the enlarged cavity 1422, and extends from the enlarged cavity 1422 into the second receiving slot 1414. In detail, the first plastics 110 cover the second plastics 120 received in the second receiving slot 1414.

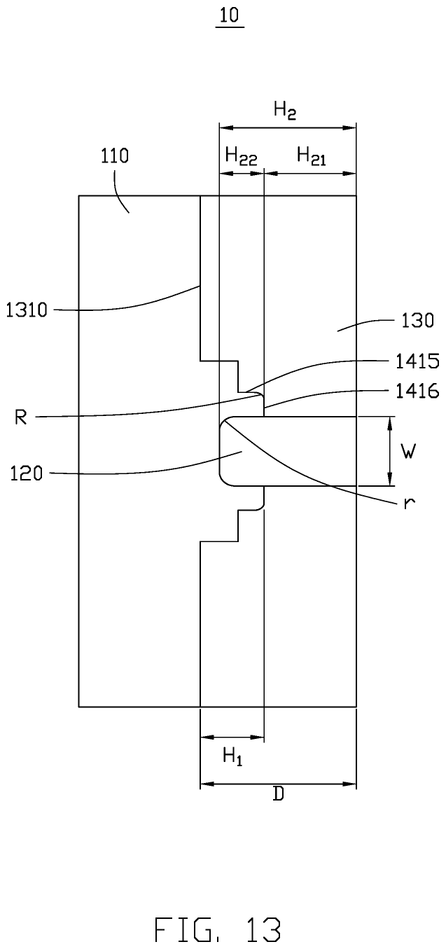

Referring to FIG. 13, in one embodiment, a thickness D of the metal substrate 130 is larger than 0.8 mm, and is less than 1.9 mm. A depth H₁ of the receiving slot 1410 is equal to or larger than 0.3 mm, and is equal to or less than 1 mm. A depth H₂ of the receiving space 1420 is in a range from 0.5 mm to 0.9 mm. Preferably, the thickness D of the metal substrate 130 is 1 mm, the depth H₁ of the receiving slot 1410 is 0.5 mm, and the depth H₂ of the receiving space 1420 is 0.8 mm.

The H₁ and H₂ also respectively represent lengths of the hole 140 and the receiving space 1420 along a direction perpendicular to the inner side 1310 of the metal substrate 130.

In one embodiment, an opening width W of the enlarged cavity 1422 is in a range from 0.6 mm to 1.5 mm. A depth H₂₁ of the enlarged cavity 1422 is larger than or equal to 0.3 mm, and is less than or equal to 0.5 mm. A depth H₂₂ of the extended cavity 1424 is in a range from 0.2 mm to 0.4 mm. Preferably, W is 1 mm, H₂₁ is 0.4 mm, and H₂₂ is 0.4 mm.

W also represents a length of the enlarged cavity 1422 along a direction parallel with the inner side of the metal substrate 130. H₂₁ represents a length of the enlarged cavity 1422 along a direction perpendicular to the inner side of the metal substrate 130. H₂₂ represents a length of the extended cavity 1424 along a direction perpendicular to the inner side of the metal substrate 130.

In one embodiment, the first plastics 110 include a first slot plastic 1110 and a second slot plastic 1120. The first slot plastic 1110 is received in the first receiving slot 1412. The second plastics 1120 are received in the second receiving slot 1414, and the second slot plastic 1120 covers a part of the second plastics 120.

In one embodiment, the first plastics 110 also include a surface plastic 1130 filled in the inner side of the metal substrate 130, and covering the first slot plastic 1110.

In one embodiment, the metal-plastic composite component 10 is a mid-frame, used in an electronic device.

In one embodiment, there are several metal substrates 130. The metal substrates 130 are spaced apart from each other and arranged in a circle. There are several first plastics 110 and several surface plastics 1130 corresponding to the metal substrates 130 respectively. The surface plastics 1130 are formed in a complete mold. Thus, the metal substrates 130 form a closed mid-frame structure.

The first slot plastic 1110, the second slot plastic 1120, the surface plastic 1130, and the second plastics 120 can be made of a same material, or also can be made of different materials. The materials can be PE, PP, PVC, ABS, or the like.

In one embodiment, one of the inner side of the metal substrate 130 and a surface of the receiving slot 1410 forms micro voids, and another of the inner side of the metal substrate 130 and a surface of the receiving slot 1410 is a smooth surface.

In detail, the micro voids fill with plastic and can improve a combination strength between the metal substrate 130 and the plastic while injecting the plastic. A diameter of each micro void is in a range from 30 μm to 80 μm, and a depth of each micro void is in a range from 30 μm to 80 μm. A surface roughness of the smooth surface of one of the inner side of the metal substrate 130 and the surface of the receiving slot 1410 is less than Ra0.8.

In one embodiment, a casing including the metal-plastic composite component 10 is also provided.

In one embodiment, an electronic device with the casing is also provided. The electronic device can be a mobile phone or a tablet, and the like.

Based on the structure of the metal-plastic composite component 10, the casing, and the electronic device, the metal substrate 130 is formed with two injecting operations while forming the metal-plastic composite component 10. A first injecting operation forms the first plastics 110 on the metal substrate 130 for enhancing a strength of the metal substrate 130 and preventing the metal substrate 130 from being deformed due to a pressure of a second injecting operation. The metal substrate 130 is counterbored for removing a deformed portion, and then the second injecting operation is executed for forming the second plastics 120 on the metal substrate 130. The strength of the combination between the metal and the plastic is enhanced. A total quality of the metal-plastic composite component 10 is improved, a probability of viewing a deformed metal substrate 130 from appearance is reduced. A user feeling of the metal-plastic composite component 10 is improved. Besides, the method is simple and in a strong operability, thus it is easy for a scale production and the efficiency of processing the metal-plastic composite component 10 is improved.

Besides, many variations and modifications can be made to the above-described embodiment(s) of the disclosure without departing substantially from the spirit and principles of the disclosure. All such modifications and variations are intended to be included herein within the scope of this disclosure and protected by the following claims. The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best use the invention and various described embodiments with various modifications as are suited to the particular use contemplated.

What is claimed is:

1. A method for producing a metal-plastic composite component, the method comprising:
forming a metal substrate with a receiving hole;
injecting first plastics into the metal substrate to form a metal-plastic blank, wherein the first plastics are filled in the receiving hole;
processing the receiving hole and the first plastics for removing a part of the first plastics by at least one cutter to form a receiving space; and
injecting second plastics into the metal-plastic blank to form the metal-plastic composite component, wherein the receiving space is filled with the second plastics.

2. The method of claim 1, wherein the receiving hole comprises a receiving slot and a through hole communicated with each other;
forming the metal substrate with the receiving hole comprises:
forming the receiving slot at an inner side of the metal substrate by the at least one cutter; and
cutting at a bottom of the receiving slot to form the through hole passing through an outer side of the metal substrate.

3. The method of claim 1, wherein the receiving hole comprises a receiving slot and a through hole communicated with each other; the metal substrate comprises a first metal substrate and a second metal substrate;
forming the metal substrate with the receiving hole comprises:
manufacturing the first metal substrate and the second metal substrate;
spacing apart the first metal substrate from the second metal substrate to form the through hole; and
processing inner sides of the first metal substrate and the second metal substrate by the at least one cutter to form the receiving slot between the first metal substrate and the second metal substrate.

4. The method of claim 2, wherein the receiving slot comprises a first receiving slot and a second receiving slot communicated with each other; the at least one cutter comprises a first cutter and a second cutter;
forming the receiving slot at the inner side of the metal substrate comprises:
forming the first receiving slot at the inner side of the metal substrate by the first cutter; and
forming the second receiving slot at the bottom of the first receiving slot by the second cutter, wherein a cross-sectional area of the first receiving slot is larger than a cross-sectional area of the second receiving slot, and the second receiving slot communicates with the through hole.

5. The method of claim 4, wherein the first plastics comprise a first slot plastic, a second slot plastic, and a hole plastic;
injecting the first plastics into the metal substrate to form the metal-plastic blank comprises:
disposing the metal substrate in a mold;
closing the mold, and injecting the first slot plastic in the first receiving slot, the second slot plastic in the second receiving slot, and the hole plastic in the through hole to form the metal-plastic blank.

6. The method of claim 5, wherein the first plastics further comprise a surface plastic;
injecting the first plastics into the metal substrate to form the metal-plastic blank comprises:
injecting the first plastics at the inner side of the metal substrate to form the surface plastic.

7. The method of claim 5, wherein the receiving space comprises an enlarged cavity and an extended cavity communicated with each other;
processing the receiving hole and the first plastics for removing a part of the first plastics comprises:
enlarging the through hole by the at least one cutter for removing the hole plastic in the through hole and forming the enlarged cavity; and
milling the enlarged cavity along a direction adjacent to the receiving slot by the at least one cutter for removing a part of the second slot plastic in the receiving slot, and forming the extended cavity.

8. The method of claim 7, wherein the second plastics comprise an enlarged plastic and an extended plastic;
injecting the second plastics into the metal-plastic blank to form the metal-plastic composite component comprises:
disposing the metal-plastic blank in the mold; and
closing the mold, and injecting the enlarged plastic into the enlarged cavity and injecting the extended plastic into the extended cavity to form the metal-plastic composite component.

9. The method of claim 1, further comprising:
etching the metal substrate to form micro voids at the inner side and the outer side of the metal substrate and a surface of the receiving hole; and
processing a surface of the outer side of the metal substrate by the at least one cutter for removing the micro voids on the outer side of the metal substrate and a part of the second plastics.

10. A metal-plastic composite component comprises:
first plastics;
second plastics, connected with the first plastics; and
a metal substrate, defining a through hole in which the first plastics and the second plastics are filled.

11. The metal-plastic composite component of claim 10, wherein the through hole comprises:
a receiving slot defined at an inner side of the metal substrate, and configured to receive the first plastics; and
a receiving space, communicated with the receiving slot and defined at an outer side of the metal substrate; and configured to receive the second plastics.

12. The metal-plastic composite component of claim 11, wherein the receiving slot comprises:
a first receiving slot defined at the inner side of the metal substrate; and
a second receiving slot defined at the bottom of the first receiving slot, wherein the second receiving slot communicates with the first receiving slot, and a cross-sectional area of the first receiving slot is larger than a cross-sectional area of the second receiving slot; and wherein the second receiving slot comprises: a sidewall, connected with the first receiving slot; and a bottom wall, having a circular chamfer at a joint with the sidewall.

13. The metal-plastic composite component of claim 10, wherein the receiving space comprises:
an enlarged cavity, defined at the outer side of the metal substrate; and
an extended cavity, communicated with the enlarged cavity, and extending from the enlarged cavity to the second receiving slot.

14. The metal-plastic composite component of claim 11, wherein a thickness of the metal substrate is larger than 0.8 mm, and is less than 1.9 mm; a depth of the receiving slot is larger than 0.3 mm, and is less than 1 mm; a depth of the receiving space is in a range from 0.5 mm to 0.9 mm.

15. The metal-plastic composite component of claim 13, wherein a depth of the enlarged cavity is larger than or equal to 0.3 mm, and is less than or equal to 0.5 mm; a depth of the extended cavity is in a range from 0.2 mm to 0.4 mm.

16. The metal-plastic composite component of claim 12, wherein the first plastics comprise:
a first slot plastic, filled in the first receiving slot;
a second slot plastic, filled in the second receiving slot; and
a surface plastic, filled in the inner side of the metal substrate, the surface plastic covering the first slot plastic.

17. The metal-plastic composite component of claim 16, wherein there are several metal substrates; the metal substrates are spaced apart from each other and arranged in a circle; there are several first plastics and several surface plastics corresponding to the metal substrates respectively; the surface plastics are formed in a complete mold.

18. The metal-plastic composite component of claim 11, wherein one of the inner side of the metal substrate and a surface of the receiving slot forms micro voids, and another of the inner side of the metal substrate and a surface of the receiving slot is a smooth surface.

19. The metal-plastic composite component of claim 11, wherein a roughness of one of the inner side of the metal substrate and the surface of the receiving slot is in a range from Ra10 to Ra30; a roughness of one of the outer side of the metal substrate and the surface of the receiving slot is in a range from Ra0.5 to Ra1.6.

20. The metal-plastic composite component of claim 10, wherein a part of the first plastic is embedded into the second plastic, or a part of the second plastic is embedded into the first plastic, or the first plastic and the second plastic are embedded with each other.
